(19) United States
(12) Patent Application Publication
(10) Pub. No.: US 2012/0185188 A1
(43) Pub. Date: Jul. 19, 2012

(54) SYSTEM AND METHOD FOR TESTING INTERNAL RESISTANCE OF BATTERY IN AN ELECTRONIC DEVICE

(75) Inventor: XIAO-DONG WANG, Shenzhen City (CN)

(73) Assignees: CHI MEI COMMUNICATION SYSTEMS, INC., Tu-Cheng (TW); SHENZHEN FUTAIHONG PRECISION INDUSTRY CO., LTD., ShenZhen City (CN)

(21) Appl. No.: 13/116,026

(22) Filed: May 26, 2011

(30) Foreign Application Priority Data
Jan. 14, 2011 (CN) 201110008130.6

(51) Int. Cl. G01R 31/36; G06F 19/00

(52) U.S. Cl. 702/63

(57) ABSTRACT

A system and method for testing an internal resistance of a battery in an electronic device include reading a first voltage of the battery in the electronic device, under the condition that the electronic device is in a standby state. The testing method further includes reading a second voltage of the battery, under the condition that a power transmission of the electronic device is at a maximum, and calculating the internal resistance of the battery according to the first voltage and the second voltage.

### BACKGROUND

1. Technical Field

Embodiments of the present disclosure relate to test technology, and in particular, to a system and method for testing internal resistance of a battery in an electronic device.

2. Description of Related Art

The capacity of a battery in an electronic device has a relationship with the internal resistance of the battery. Some test methods utilize this relationship to determine the capacity of the battery. However, such methods need additional circuits to measure the internal resistance in the electronic device and thus, it is difficult and inconvenient to assess the internal resistance in determining the capacity of the battery.

### BRIEF DESCRIPTION OF THE DRAWINGS

FIG. 1 is a schematic diagram of one embodiment of an electronic device including a testing system.

FIG. 2 is a block diagram of one embodiment of the testing system of FIG. 1.

FIG. 3 is a flowchart of one embodiment of a method for testing an internal resistance of a battery in an electronic device, such as, that of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

In general, the word “module,” as used herein, refers to logic embodied in hardware or firmware, or to a collection of software instructions, written in a programming language, for example, Java, C, or Assembly. One or more software instructions in the modules may be embedded in firmware, such as an EPROM. It will be appreciated that modules may comprised connected logic units, such as gates and flip-flops, and may comprise programmable units, such as programmable gate arrays or processors. The modules described herein may be implemented as either software and/or hardware modules and may be stored in any type of computer-readable medium or other computer storage system.

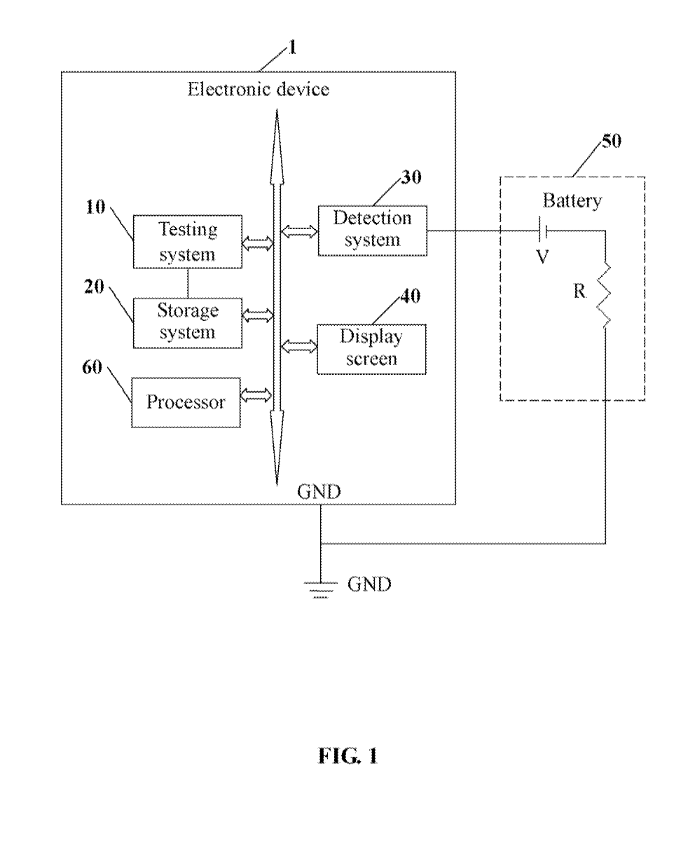

FIG. 1 is a schematic diagram of one embodiment of an electronic device 1 including a testing system 10. The electronic device 1 also includes a detection system 30 and a display screen 40. The detection system 30 may be connected to a battery 50 of the electronic device 1.

The testing system 10 may calculate and display an internal resistance of the battery 50 according to the voltages of the battery 50.

The detection system 30 can detect the voltages of the battery 50. In some embodiments, the detection system 30 may be an analog-to-digital converter (ADC) in the electronic device 1. The display screen 40 may display data of the electronic device 1. The battery 50 may be a voltage source V connecting to a resistance R in series. The resistance R represents the internal resistance of the battery 50. As the internal resistance of the battery 50 increases, the capacity of the battery 50 may decrease.

The electronic device 1 further includes a storage system 20 and at least one processor 60. The storage system 20 may store data of the electronic device 1. The storage system 20 may be a memory of the electronic device 1, or an external storage card, such as a smart media (SM) card, or a secure digital (SD) card. The at least one processor 60 executes one or more computerized codes of the electronic device 1 and other applications, to provide the functions of the testing system10.

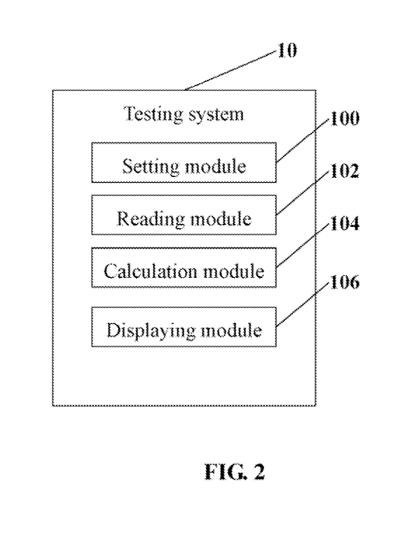

FIG. 2 is a block diagram of one embodiment of the testing system 10 of FIG. 1. In some embodiments, the testing system 10 includes a setting module 100, a reading module 102, a calculation module 104, and a displaying module 106. The modules 100, 102, 104, and 106 comprise computerized codes in the form of one or more programs that are stored in the storage system 20. The computerized code includes instructions that are executed by the processor 60 to provide functions for the modules 100, 102, 104, and 106. Details of these operations follow.

The setting module 100establishes and displays a virtual button on the display screen 50, representing an invoking function to view the internal resistance of the battery 50. The virtual button may be an image of a keystroke or an icon. To see the internal resistance, the user may tap, click, or otherwise select the virtual button.

The reading module 102 reads a first voltage of the battery 50 in the electronic device 1 by means of the detection system 30, when the electronic device 1 is started and in a standby state. In some embodiments, the battery 50 of the electronic device 1 is under minimum working load when the electronic device 1 is started and in the standby state.

The reading module 102 further reads a second voltage of the battery 50 from the detection system 30, when a power transmission of the electronic device 1 is at a maximum. The power transmission at the maximum represents that the battery 50 of the electronic device 1 is under a maximum load. In some embodiments, the power transmission at the maximum may be reached when, for example, the electronic device 1 is used to make a phone call or connect to a network.

The calculation module 104 calculates the internal resistance of the battery 50 according to the first voltage and the second voltage. The internal resistance of the battery 50 is calculated using a formula of “(V₁−V₂)÷I”, that is, (V₁−V₂) divided by I. “V₁” represents the first voltage, V₂ represents the second voltage, and “I” represents a predetermined factory-set current value which value is stored in the storage system 20. The predetermined current value is determined when the power transmission of the electronic device 1 is at the maximum.

The displaying module 106 executes the invoking function to display the internal resistance on the display screen 40, when the virtual button is tapped, clicked or selected.

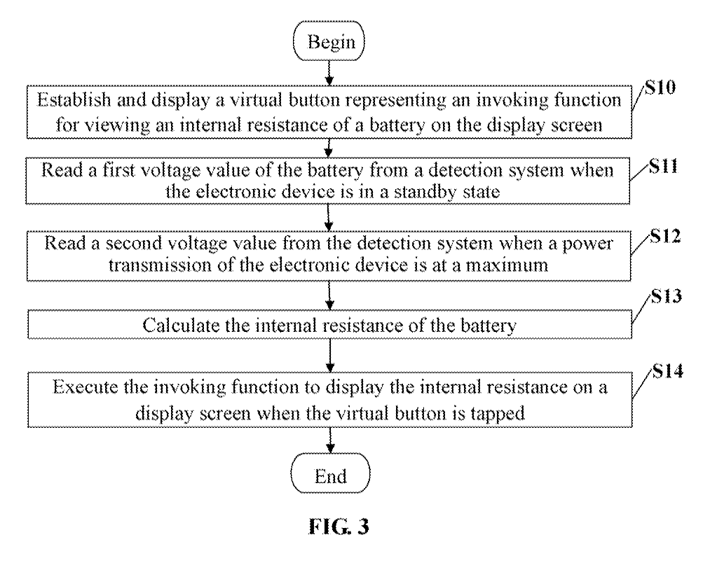

FIG. 3 is a flowchart of one embodiment of a method for testing an internal resistance of a battery in an electronic device, such as, that of FIG. 1. Depending on the embodiment, additional blocks may be added, others removed, and the ordering of the blocks may be changed.

In block S10, the setting module 100 establishes and displays a virtual button representing an invoking function for viewing the internal resistance of the battery 50 on the display screen 40. The virtual button may be an image of a keystroke or an icon displayed by the electronic device 1.

In block S11, the reading module 102 reads a first voltage of the battery 50 in the electronic device 1 from the detection system 30, when the electronic device 1 is started and in a standby state.

In block S12, the reading module 102 further reads a second voltage of the battery 50 from the detection system 30, when a power transmission of the electronic device 1 is at a maximum. In some embodiments, the power transmission at the maximum may be reached when, for example, the electronic device 1 is used to make a phone call or connect to a network.

In block S13, the calculation module 104 calculates the internal resistance of the battery 50 according to the first voltage and the second voltage. The internal resistance of the battery 50 is calculated using a formula of (V₁−V₂)÷I. V₁” represents the first voltage, “V₂” represents the second voltage, and “I” represents a predetermined factory-set current value which value is stored in the storage system 20. The predetermined current value is determined when the power transmission of the electronic device 1 is at the maximum.

In block S14, the displaying module 106 executes the invoking function to display the internal resistance on the display screen 40, upon the condition that the virtual button is tapped, clicked or selected.

It should be emphasized that the described exemplary embodiments are merely possible examples of implementations, and set forth for a clear understanding of the principles of the present disclosure. Many variations and modifications may be made to the-described exemplary embodiments without departing substantially from the spirit and principles of the present disclosure. All such modifications and variations are intended to be comprised herein within the scope of this disclosure and the-described inventive embodiments, and the present disclosure is protected by the following claims.

What is claimed is:

1. A computer-implemented method for testing an internal resistance of a battery in an electronic device, the method comprising:
reading a first voltage of the battery in the electronic device under the condition that the electronic device is in a standby state;
reading a second voltage of the battery under the condition that a power transmission of the electronic device is at a maximum; and
calculating the internal resistance of the battery according to the first voltage and the second voltage.

2. The method as claimed in claim 1, further comprises:
establishing and displaying a virtual button representing an invoking function for viewing the internal resistance of the battery on the display screen; and
executing the invoking function to display the internal resistance a display screen of the electronic device, upon the condition that the virtual button is tapped, clicked or selected.

3. The method as claimed in claim 2, wherein the virtual button may be an image of a keystroke or an icon displayed by the electronic device.

4. The method as claimed in claim 1, wherein the internal resistance of the battery is calculated using a formula of (V₁−V₂)÷I, “V₁” representing the first voltage, “V₂” representing the second voltage, and “I” representing a predetermined current value when the power transmission of the electronic device is at the maximum.

5. The method as claimed in claim 4, wherein the power transmission of the electronic device is at the maximum when the electronic device makes a phone call or connects to a network.

6. A storage medium storing a set of instructions, the set of instructions capable of executed by a processor to perform a method for testing an internal resistance of a battery in an electronic device, the method comprising:
reading a first voltage of the battery in the electronic device, under the condition that the electronic device is in a standby state;
reading a second voltage of the battery under the condition that a power transmission of the electronic device is at a maximum; and
calculating the internal resistance of the battery according to the first voltage and the second voltage.

7. The storage medium as claimed in claim 6, wherein the method further comprises:
establishing and displaying a virtual button representing to an invoking function for viewing the internal resistance of the battery on the display screen; and
executing the invoking function to display the internal resistance a display screen of the electronic device, upon the condition that the virtual button is tapped, clicked or selected.

8. The storage medium as claimed in claim 7, wherein the virtual button may be an image of a keystroke or an icon displayed by the electronic device.

9. The storage medium as claimed in claim 6, wherein the internal resistance of the battery is calculated using a formula of (V₁−V₂)÷I, “V₁” representing the first voltage, “V₂” representing the second voltage, and “I” representing a predetermined current value when the power transmission of the electronic device is at the maximum.

10. The storage medium as claimed in claim 9, wherein the power transmission of the electronic device is at the maximum when the electronic device makes a phone call or connects to a network.

11. An electronic device, comprising:
a storage system;
a display screen;
a processor; and
one or more programs stored in the storage system, executable by the processor, the one or more programs comprising:
a reading module operable to read a first voltage of a battery in the electronic device, under the condition that the electronic device is in a standby state;
the reading module further operable to read a second voltage of the battery under the condition that a power transmission of the electronic device is at a maximum; and
a calculation module operable to calculate the internal resistance of the battery according to the first voltage and the second voltage.

12. The electronic device as claimed in claim 11, wherein the one or more programs further comprises:
a setting module operable to establish and display a virtual button representing an invoking function for viewing the internal resistance of the battery; and
a displaying module operable to execute the invoking function to display the internal resistance a display screen of the electronic device, upon the condition that the virtual button is tapped, clicked or selected.

13. The electronic device as claimed in claim 12, wherein the virtual button may be an image of a keystroke or an icon displayed by the electronic device.

14. The electronic device as claimed in claim 11, wherein the calculation module calculates the internal resistance of the battery using a formula of (V₁−V₂)÷I, “V₁” representing the first voltage, “V₂” representing the second voltage, and “I” representing a predetermined current value when the power transmission of the electronic device is at the maximum.

15. The electronic device as claimed in claim 14, wherein the power transmission of the electronic device is at the maximum when the electronic device makes a phone call or connects to a network.
